(19) United States
(12) Patent Application Publication
(10) Pub. No.: US 2024/0402481 A1
(43) Pub. Date: Dec. 5, 2024

(54) OPTICAL PATH CONTROL MEMBER AND DISPLAY DEVICE COMPRISING SAME

(71) Applicant: LG INNOTEK CO., LTD., Seoul (KR)

(72) Inventors: Jun Sik SHIN, Seoul (KR); Jong Tae KWON, Seoul (KR)

(21) Appl. No.: 18/724,890

(22) PCT Filed: Dec. 12, 2022
(86) PCT No.: PCT/KR2022/020161

§ 371 Date: Jun. 27, 2024

(30) Foreign Application Priority Data
Dec. 28, 2021 (KR) 10-2021-0190247

(51) Int. Cl. G02B 26/00; G02F 1/1335; G02F 1/167; H10K 50/85

(52) U.S. Cl. CPC G02B 26/004; G02F 1/167; G02F 1/1335; H10K 50/85

(57) ABSTRACT

An optical path control member according to an embodiment includes a first substrate; a first electrode disposed on the first substrate; a second substrate disposed on the first substrate; a second electrode disposed under the second substrate; and a light conversion unit including a plurality of accommodating parts disposed between the first electrode and the second electrode and in which a light conversion material is disposed, wherein the first substrate includes a first-first region overlapping the accommodating part and a first-second region disposed at an edge of the first substrate, the second substrate includes a second-first region overlapping the accommodating part and a second-second region disposed at an edge of the second substrate, the first electrode includes a first-first electrode part disposed on the first-first region and the first-second region and a first-second electrode disposed on the first-second region, the second electrode includes a second-first electrode part disposed on the second-first region and the second-second region and a second-second electrode part disposed on the second-second region, an area of the first-first electrode part is greater than an area of the first-second electrode part, and an area of the second-first electrode part is greater than an area of the second-second electrode part.

### TECHNICAL FIELD

An embodiment relates to an optical path control member and a display device including the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may control a movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user's environment and a switchable light blocking film that allow the user to turn on/off the viewing angle control according to the surrounding environment or the user's environment.

Such a switchable light blocking film may be implemented by converting a pattern part into a light transmitting part and a light blocking part by filling the inside of the pattern part with particles that may move when a voltage is applied and a dispersion liquid for dispersing the particles and by dispersing and aggregating the particles.

The optical path control member needs to apply a voltage to control a user's viewing angle. Accordingly, a lower electrode and an upper electrode may be disposed on lower and upper portions of the optical path control member, respectively.

In this case, the lower electrode and the upper electrode may be provided as transparent electrodes for luminance of the optical path control member. Such a transparent electrode has high resistance characteristics. Accordingly, as the area of the transparent electrode increases, there is a problem in that an electric field is uneven between a central portion and a peripheral portion of the electrode.

As a result, there is a problem in that the optical conversion characteristics of the central and peripheral portions of the optical path control member become non-uniform.

Accordingly, in order to solve the above problems, an optical path control member having a new structure is required.

### DISCLOSURE

### Technical Problem

An embodiment provides an optical path control member with improved reliability.

### Technical Solution

An optical path control member according to an embodiment includes a first substrate; a first electrode disposed on the first substrate; a second substrate disposed on the first substrate; a second electrode disposed under the second substrate; and a light conversion unit including a plurality of accommodating parts disposed between the first electrode and the second electrode and in which a light conversion material is disposed, wherein the first substrate includes a first-first region overlapping the accommodating part and a first-second region disposed at an edge of the first substrate, the second substrate includes a second-first region overlapping the accommodating part and a second-second region disposed at an edge of the second substrate, the first electrode includes a first-first electrode part disposed on the first-first region and the first-second region and a first-second electrode disposed on the first-second region, the second electrode includes a second-first electrode part disposed on the second-first region and the second-second region and a second-second electrode part disposed on the second-second region, an area of the first-first electrode part is greater than an area of the first-second electrode part, and an area of the second-first electrode part is greater than an area of the second-second electrode part.

### Advantageous Effects

A first electrode and a second electrode of the optical path control member according to the embodiment may include electrode parts having different areas, materials, thicknesses, resistances, transparency, and conductivity. Accordingly, a luminance of the optical path control member can be maintained. Additionally, the driving characteristics of the optical path control member can be improved.

That is, the optical path control member according to the embodiment may change a viewing angle by allowing light passing through the optical path control member to be transmitted by a first electrode part of a first electrode and the second electrode.

In addition, in the optical path control member according to the embodiment, resistance unevenness of the optical path control member may be reduced by a second electrode part of the first electrode and the second electrode.

Accordingly, electric field non-uniformity in a region of the optical path control member may be reduced. Accordingly, the optical path control member according to the embodiment may have improved light conversion characteristics. Accordingly, the optical path control member according to the embodiment may have improved driving characteristics.

### DESCRIPTION OF DRAWINGS

FIG. 1 is a view showing a perspective view of an optical path control member according to an embodiment.

FIGS. 2 and 3 are cross-sectional views taken along a A-A′ region of FIG. 1.

FIG. 4 is a top view of a lower substrate of an optical path control member according to an embodiment.

FIG. 5 is a cross-sectional view taken along a B-B′ region of FIG. 4.

FIG. 6 is a top view of an upper substrate of an optical path control member according to an embodiment.

FIG. 7 is a cross-sectional view taken along a C-C′ region of FIG. 6.

FIG. 8 is another cross-sectional view taken along a B-B′ region of FIG. 4.

FIG. 9 is another cross-sectional view taken along a C-C′ region of FIG. 6.

FIGS. 10 and 11 are cross-sectional views of a display device to which an optical path control member according to an embodiment is applied.

FIGS. 12 to 14 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings. The optical path control member described below may be a switchable light blocking film that operates in public mode and light blocking mode depending on the application of power.

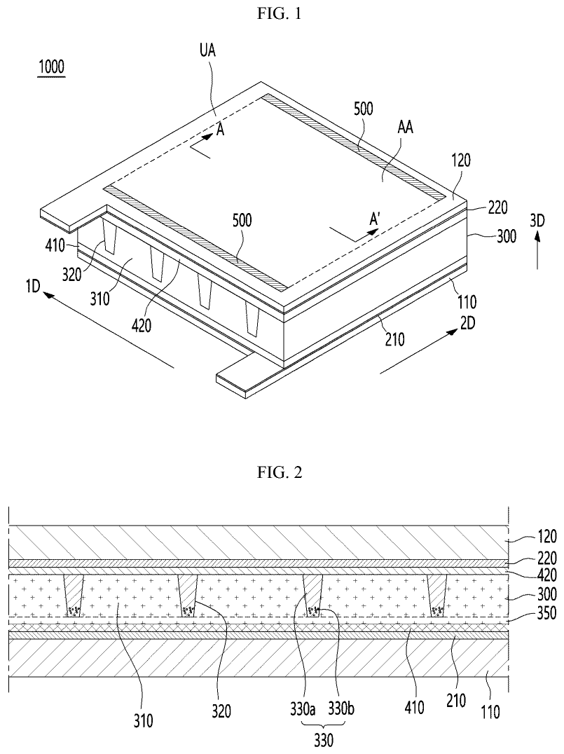

FIG. 1 is a diagram showing a perspective view of an optical path control member according to an embodiment.

Referring to FIG. 1, an optical path control member 1000 according to an embodiment may include a first substrate 110, a second substrate 120, a first electrode 210, a second electrode 220, and a light conversion unit 300.

In addition, the optical path control member 1000 may include an active region AA and an inactive region UA. The active region AA is a region in which light conversion occurs in the optical path control member. In addition, the inactive region UA is a region in which light conversion does not occur in the optical path control member. That is, the inactive region UA may be a bezel region of the optical path control member.

The first substrate 110 may support the first electrode 210. The first substrate 110 may be rigid or flexible.

In addition, the first substrate 110 may be transparent. For example, the first substrate 110 may include a transparent substrate capable of transmitting light.

The first substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example, but the embodiment is not limited thereto.

In addition, the first substrate 110 may be a flexible substrate having flexible characteristics.

Further, the first substrate 110 may be a curved or bended substrate. That is, the optical path control member including the first substrate 110 may also be formed to have flexible, curved, or bent characteristics. Accordingly, the optical path control member according to the embodiment may be changed to various designs.

The first substrate 110 may extend in a first direction 1A, a second direction 2A, and a third direction 3A.

In detail, the first substrate 110 may include the first direction 1A corresponding to a length or width direction of the first substrate 110. In addition, the first substrate 110 may include a second direction 2A extending in a direction different from the first direction 1A and corresponding to the length or width direction of the first substrate 110. In addition, the first substrate 110 may include a third direction 3A extending in a direction different from the first direction 1A and the second direction 2A and corresponding to a thickness direction of the first substrate 110.

Hereinafter, for convenience of description, the first direction 1A will be described as the length direction of the first substrate 110, the second direction 2A will be described as the width direction of the first substrate 110, and the third directions 3A will be described as the thickness direction of the first substrate 110.

The first substrate 110 may have a thickness within a set range. For example, the first substrate 110 may have a thickness of 25 μm to 150 μm.

The first electrode 210 may be disposed on one surface of the first substrate 110. In detail, the first electrode 210 may be disposed on an upper surface of the first substrate 110. That is, the first electrode 210 may be disposed between the first substrate 110 and the second substrate 120.

The first electrode 210 may be arranged as a single layer or multiple layers. In detail, a single-layer first electrode 210 may be disposed in one region of the first substrate 110. In addition, a multi-layered first electrode 210 may be disposed in another region of the first substrate 110.

The first electrode 210 will be described in detail below.

The second substrate 120 may be disposed on the first substrate 110. In detail, the second substrate 120 may be disposed on the first electrode 210 on the first substrate 110.

The second substrate 120 may include the same or similar material as the first substrate 110 described above.

In addition, the second substrate 120 may have a thickness the same as or similar to that of the first substrate 110 described above. For example, the second substrate 120 may have a thickness of 25 μm to 150 μm.

In addition, the second substrate 120 may extend in the first direction 1D, second direction 2D, and third direction 3D corresponding to first substrate 110 described above. Hereinafter, for convenience of description, the first direction 1A will be described as the length direction of the second substrate 120, the second direction 2A the second direction 2A will be described as the width direction of the second substrate 120, and the third directions 3A will be described as the thickness direction of the second substrate 120.

The second electrode 220 may be disposed on one surface of the second substrate 120. In detail, the second electrode 220 may be disposed on a lower surface of the second substrate 120. That is, the second electrode 220 may be disposed on one surface of the second substrate 120 in which the second substrate 120 and the first substrate 110 face each other. That is, the second electrode 220 may be disposed to face the first electrode 210 on the first substrate 110. That is, the second electrode 220 may be disposed between the first electrode 210 and the second substrate 120.

The second electrode 220 may be arranged as a single layer or multilayer. In detail, a single-layer second electrode 220 may be disposed in one region of the second substrate 120. In addition, a multi-layered second electrode 220 may be disposed in another region of the second substrate 120.

The second electrode 220 will be described in detail below.

The first substrate 110 and the second substrate 120 may have the same or different sizes.

In detail, the first length extending in the first direction (1D) of the first substrate 110 may be the same as or similar to the second length extending in the first direction 1D of the second substrate 120.

For example, the first length and the second length may have a size of 300 mm to 400 mm.

In addition, the first width extending in the second direction (2D) of the first substrate 110 may have the same or similar to the second width extending in the second direction 2D of the second substrate 120.

For example, the first width and the second width may have a size of 150 mm to 200 mm.

The first substrate 110 and the second substrate 120 may include protrusion. For example, the first substrate 110 may include a first protrusion PA1, and the second substrate 120 may include a second protrusion PA2.

The first protrusion PA1 and the second protrusion PA2 may or may not overlap each other in the third direction 3D.

Each of the first protrusion PA1 and the second protrusion PA2 may include a connection region connected to an external (flexible) printed circuit board.

In detail, a first connection region CA1 may be disposed in the first protrusion PA1, and a second connection region CA2 may be disposed in the second protrusion PA2.

A conductive material may be exposed on upper surfaces of the first connection region CA1 and the second connection region CA2, respectively. For example, the first electrode 210 may be exposed in the first connection region CA1. In addition, the second electrode 220 may be exposed in the second connection region CA2. As a result, the optical path control member can be electrically connected to an external (flexible) printed circuit board through the first connection region CA1 and the second connection region CA2.

For example, pad parts may be disposed on the first connection region CA1 and the second connection region CA2. In addition, a conductive adhesive including at least one of an anisotropic conductive film (ACF) and an anisotropic conductive paste (ACP) may be disposed between the pad part and the (flexible) printed circuit board. As a result, the optical path control member and the (flexible) printed circuit board can be connected.

Alternatively, a conductive adhesive including at least one of an anisotropic conductive film ACF and an anisotropic conductive paste ACP may be disposed between the first connection region CA1 and the second connection region CA2 and the (flexible) printed circuit board. Accordingly, the optical path control member may be directly connected to the (flexible) printed circuit board without a pad part.

The light conversion unit 300 may be disposed between the first substrate 110 and the second substrate 120. Specifically, the light conversion unit 300 may be disposed between the first electrode 210 and the second electrode 220.

An adhesive layer or a buffer layer may be disposed in at least one of regions between the light conversion unit 300 and the first substrate 110 or the region between the light conversion unit 300 and the second substrate 120. The first substrate 110, the second substrate 120, and the light conversion unit 300 may be adhered by the adhesive layer and/or the buffer layer.

For example, a buffer layer 410 may be disposed between the first electrode 210 and the light conversion unit 300. Accordingly, adhesion between the first electrode 210 and the light conversion unit 300 including different materials may be improved.

The buffer layer 410 may have a thickness within a set range. For example, the buffer layer 410 may have a thickness of less than 1 μm.

Also, an adhesive layer 420 may be disposed between the second electrode 220 and the light conversion unit 300. Accordingly, the second substrate 120 and the light conversion unit 300 may be adhered to each other.

The adhesive layer 420 may have a thickness within a predetermined range. For example, the adhesive layer 420 may have a thickness of about 10 μm to about 30 μm.

The light conversion unit 300 may include a plurality of partition wall parts 310 and a accommodating part 320. A light conversion material 330 including light conversion particles and a dispersion liquid may be disposed inside the accommodating part 320. The light conversion particles may move according to an application of a voltage. Also, the dispersion liquid may disperse the light conversion particles. The light transmission characteristic of the optical path control member may be changed by the light conversion particles.

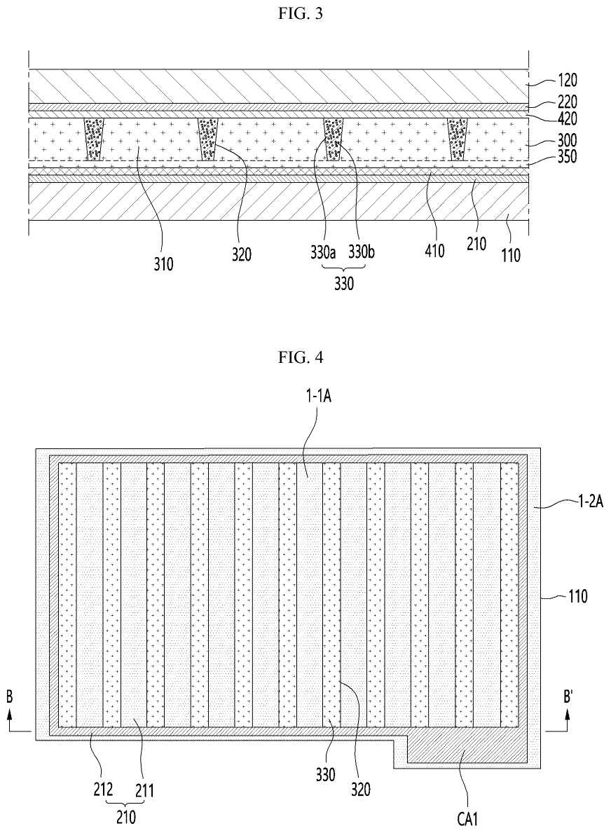

FIGS. 2 and 3 are cross-sectional views taken along a A-A′ region of FIG. 1.

Referring to FIGS. 2 and 3, the light conversion unit 300 may include a plurality of partition wall parts 310, a plurality of accommodating parts 320, and a base part 350.

The light conversion unit 300 may include a plurality of partition wall parts 310 and a plurality of accommodating part 320. The partition wall part 310 and the accommodating part 320 may be alternately disposed. That is, one accommodating part 320 may be disposed between two adjacent partition wall parts 310. Also, one partition wall part 310 may be disposed between two adjacent accommodating parts 320.

The base part 350 may be disposed under the accommodating part 320. Specifically, the base part 350 may be disposed between the accommodating part 320 and the buffer layer 410. More specifically, the base part 350 may be disposed between a lower surface of the accommodating part 320 and an upper surface of the buffer layer 410. Accordingly, the light conversion unit 300 may be adhered to the first electrode 210 through the base part 350 and the buffer layer 410.

Also, an adhesive layer 420 may be disposed between the partition wall part 310 and the second electrode 220. The light conversion unit 300 and the second electrode 220 may be adhered through the adhesive layer 420.

The base part 350 is a region formed when a resin material constituting the partition wall part 310 and the accommodating part 320 is released from a mold member. Accordingly, the base part 350 and the partition wall part 310 may include the same material. That is, the base part 350 and the partition wall part 310 may be integrally formed.

The partition wall part 310 may transmit light. Also, the light transmittance of the accommodating part 320 may be changed by the application of a voltage.

Specifically, the light conversion material 330 may be disposed inside the accommodating part 320. The light transmittance of the accommodating part 320 may be changed by the light conversion material 330. The light conversion material 330 may include the light conversion particles 330b and the dispersion liquid 330a. Also, the light conversion material 300 may further include a dispersant preventing aggregation of the light conversion particles 330b.

The light conversion particles 330b disposed in the dispersion 330a may move by the application of the voltage. For example, referring to FIG. 2, surfaces of the light conversion particles 330b may be negatively charged. Also, a positive voltage may be applied to at least one of the first electrode 210 and the second electrode 220. Accordingly, the light conversion particles 330b may be moved toward the first electrode 210 or the second electrode 220. Accordingly, the accommodating part 320 may become a light transmitting part.

For example, the second electrode 220 may be in a positive voltage or a ground voltage state, and the first electrode 220 may have a positive voltage greater than that of the second electrode. The light conversion particles 330b may move in a direction toward the first electrode 210 and aggregate due to attraction.

Accordingly, the optical path control member may be driven in a share mode.

Also, referring to FIG. 3, a negative voltage may be applied to at least one of the first electrode 210 and the second electrode 220. The light conversion particles 330b may be dispersed from the dispersion liquid 330a by a repulsive force. Accordingly, the accommodating part 320 may become a light blocking part.

Accordingly, the optical path control member may be driven in a privacy mode.

The optical path control member 1000 may include a sealing part 500. The sealing part 500 may be disposed at an edge of the optical path control member 1000. The sealing part 500 may seal both ends of the accommodating part 320. Accordingly, the light conversion material 330 inside the accommodating part 320 may be sealed by the sealing part 500.

The sealing part 500 may be formed by filling the inside of the cutting region formed in the second substrate 120 with a sealing material.

As described above, the optical path control member includes a first electrode 210 and a second electrode 220. The first electrode 210 and the second electrode 220 may include a transparent electrode to allow light to be transmitted.

However, the transparent electrode may have higher resistance than a metal electrode. Accordingly, when areas of the first electrode 210 and the second electrode 220 increase, a resistance difference may occur in a central portion and a peripheral portion of the electrode. Due to the resistance difference, the electric field difference may become non-uniform in the central portion and the peripheral portion of the optical path control member.

Accordingly, light conversion characteristics may become uneven in the central portion and the peripheral portion of the optical path control member, thereby deteriorating driving characteristics of the optical path control member.

Hereinafter, the first electrode 210 and the second electrode 220 capable of solving the above problems will be described.

Referring to FIGS. 4 and 5, the first electrode 210 disposed on the first substrate 110 will be described.

Referring to FIGS. 4 and 5, the first substrate 110 may include a first-first region 1-1A and a first-second region 1-2A. The first-first region 1-1A may be defined as an active region. Specifically, the first-first region 1-1A may be a region through which light is transmitted. That is, the first-first region 1-1A may be defined as a light conversion region.

The first-first region 1-1A may be a region corresponding to the active region AA of the optical path control member described above.

A plurality of accommodating parts 320 and the light conversion material 330 disposed inside the accommodating part 320 may be disposed in the first-first region 1-1A. Accordingly, the path of light may be changed in the first-first region 1-1A. Accordingly, the viewing angle of the user may be changed.

That is, the first-first region 1-1A may be defined as a region overlapping the accommodating part 320.

Also, the first-second region 1-2A may be defined as an inactive region. Specifically, the first-second region 1-2A may be defined as a region through which light is not transmitted. That is, the first-second region 1-2A may be defined as a region through which light is not converted.

The first-second region 1-2A may be a region corresponding to the inactive region UA of the optical path control member described above.

The sealing part 500 and the first connection region CA1 may be disposed in the first-second region 1-2A. Accordingly, the external printed circuit board and the first connection region CA1 may be connected at the first-second region 1-2A.

The first electrode 210 may include a first-first electrode part 211 and a first-second electrode part 212. The first-first electrode part 211 may be disposed on at least one of the first-first region 1-1A and the first-second region 1-2A. Specifically, the first-first electrode part 211 may be disposed on the first-first region 1-1A and the first-second region 1-2A.

The first-second electrode part 212 may be disposed on at least one of the first-first region 1-1A and the first-second region 1-2A. In detail, the first-second electrode part 212 may be disposed on the first-second region 1-2A. The first-second electrode part 212 may be disposed on an entire region or a partial region of the first-second region 1-2A.

The first-second electrode part 212 may be disposed on an edge of the first substrate 110. In detail, the first-second electrode part 212 may be disposed to extend along an edge of the first substrate 110.

Accordingly, the first-first electrode part 211 may be disposed in contact with the first substrate 110. Also, the first-second electrode part 212 may not be in contact with the first substrate 110. That is, the first-first electrode part 211 may be disposed on the first substrate 110. Also, the first-second electrode part 212 may be disposed on the first-first electrode part 211.

The first-first electrode part 211 and the first-second electrode part 212 may be disposed in different areas.

In detail, an area of the first-first electrode part 211 may be greater than an area of the first-second electrode part 212. That is, an area of the first-first electrode part 211 disposed on the first-first region 1-1A and the first-second region 1-2A may be greater than an area of the first-second electrode part 212 disposed on the first-second region 1-2A.

In addition, the first-first electrode part 211 and the first-second electrode part 212 may have different thicknesses.

Specifically, the thickness T1-1 of the first-first electrode part 211 may be smaller than the thickness T1-2 of the first-second electrode part 212.

For example, the thickness T1-1 of the first-first electrode part 211 may be in a range of 0.1 μm to 0.5 μm. When the thickness T1-1 of the first-first electrode part 211 is less than 0.1 μm, it may be difficult to implement in a process. Also, the sheet resistance of the first-first electrode part 211 may increase. Also, when the thickness T1-1 of the first-first electrode part 211 exceeds 0.5 μm, a thickness of the optical path control member may increase.

In addition, the thickness T1-2 of the first-second electrode part 212 may be 0.1 μm to 5 μm. When the thickness T1-2 of the first-second electrode part 212 is smaller than 0.1 μm, it may be difficult to implement in a process. In addition, when the thickness T1-2 of the first-second electrode part 212 exceeds 5 μm, a thickness of the optical path control member may increase.

The thickness T1-1 of the first-first electrode part 211 may be smaller than the thickness T1-2 of the first-second electrode part 212 within the above range.

In addition, the first-first electrode part 211 and the first-second electrode part 212 may include different materials.

The first-first electrode part 211 may include a transparent material. That is, the first-first electrode part 211 may include a transparent electrode. For example, the first-first electrode part 211 may include a metal oxide such as indium tin oxide, indium zinc oxide, copper oxide, tin oxide, zinc oxide, titanium oxide, etc.

Accordingly, even if the first-first electrode part 211 is disposed on the first-first region 1-1A of the first substrate 110, the luminance of the optical path control member may be maintained.

The first-second electrode part 212 may include an opaque or translucent material. The first-second electrode part 212 may include a metallic material. For example, the first-second electrode part 212 may include at least one of chromium (Cr), nickel (Ni), copper (Cu), aluminum (Al), silver (Ag), molybdenum (Mo), Gold (Au), titanium (Ti), and alloys thereof.

The first-second electrode part 212 is disposed on the first-second region 1-2A of the first substrate 110. Accordingly, even if the first-second electrode part 212 includes an opaque metallic material, it does not affect the transmittance of light passing through the optical path control member.

In addition, the first-first electrode part 211 and the first-second electrode part 212 may have different resistance values.

The resistance of the first-first electrode part 211 may be greater than that of the first-second electrode part 212. In detail, a sheet resistance of the first-first electrode part 211 may be greater than that of the first-second electrode part 212.

For example, the sheet resistance of the first-first electrode part 211 may be 50Ω/□ to 2000Ω/□. Also, the sheet resistance of the first-second electrode part 212 may be 0.1Ω/□ to 50 Ω/□.

Accordingly, only an electrode having a high resistance may be disposed in the first-first region 1-1A, which is the active region of the first substrate 110. In addition, an electrode having a high resistance and a metal having a low resistance may be disposed together in the first-second region 1-2A, which is the inactive region of the first substrate 110.

Accordingly, the non-uniformity of the resistance may be reduced in the entire region of the first substrate 110. That is, when only the first-first electrode part 211 having a high resistance is disposed on the first substrate 110, the resistance may be increased while extending from the central portion of the first substrate 110 to the peripheral region. Accordingly, the first-second electrode part 212 having a low resistance may be additionally disposed in the first-second region 1-2A. Accordingly, the resistance non-uniformity may be reduced in the first substrate 110.

Accordingly, it is possible to minimize the change in the light conversion characteristics of the optical path control member for each region due to the electric field non-uniformity according to the resistance difference. Accordingly, driving characteristics of the optical path control member may be improved.

In addition, the first-first electrode part 211 and the first-second electrode part 212 may have different transparency.

The transparency of the first-first electrode part 211 may be greater than that of the first-second electrode part 212. Specifically, the first-first electrode part 211 may be more transparent than the first-second electrode part 212.

Accordingly, even if the first-first electrode part 211 is disposed on the first-first region 1-1A of the first substrate 110, light passing through the optical path control member may pass through the first-first electrode part 211.

Also, the first-second electrode part 212 may include an opaque metallic material. However, the first-second electrode part 212 is disposed on the first-second region 1-2A through which light is not transmitted. Accordingly, it does not affect the transmittance of light passing through the optical path control member.

In addition, the first-first electrode part 211 and the first-second electrode part 212 may have different conductivity.

The conductivity of the first-second electrode part 212 may be greater than that of the first-first electrode part 211.

Since the conductivity of the first-second electrode part 212 is greater than that of the 1-1-th electrode part 211, electrical connection characteristics between the optical path control member and the external printed circuit board may be improved.

That is, the first-second electrode part 212 is disposed in the first connection region CA1 of the first-second region 1-2A. Accordingly, the first connection region CA1 may include a material having a high conductivity. Accordingly, when the optical path control member is connected to the external printed circuit board through the first connection region CA1, electrical connection characteristics may be improved.

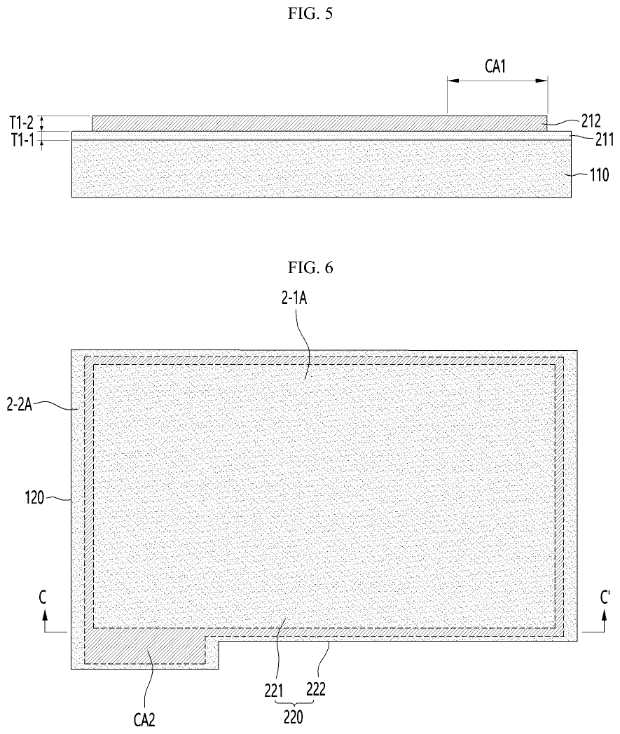

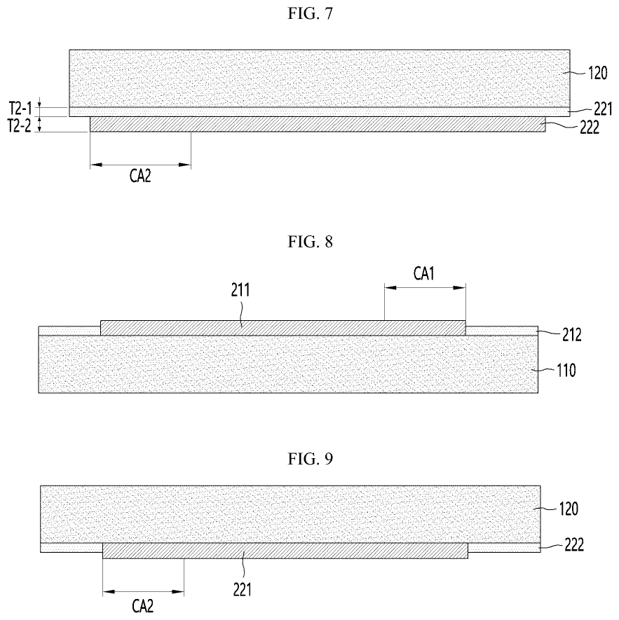

Hereinafter, the second electrode 210 disposed on the second substrate 120 will be described with reference to FIGS. 6 and 7.

Referring to FIGS. 6 and 7, the second substrate 120 may include a second-first region 2-1A and a second-second region 2-2A. The second-first region 2-1A may be defined as an active region. Specifically, the second-first region 2-1A may be a region through which light is transmitted. That is, the second-first region 2-1A may be defined as a light conversion region.

The second-first region 2-1A may be a region corresponding to the active region AA of the optical path control member described above.

A plurality of accommodating parts 320 and the light conversion material 330 disposed inside the accommodating part 320 may be disposed in the second-first region 2-1A. The path of light may be changed in the second-first region 2-1A. Accordingly, the viewing angle of the user may be changed.

That is, the second-first region 2-1A may be defined as a region overlapping the accommodating part 320.

Also, the second-second region 2-2A may be defined as an inactive region. Specifically, the second-second region 2-2A may be defined as a region through which light is not transmitted. That is, the second-second region 2-2A may be defined as a region through which light is not converted.

The second-second region 2-2A may be a region corresponding to the inactive region UA of the optical path control member described above.

The sealing part 500 and the second connection region CA2 may be disposed in the second-second region 2-2A. Accordingly, the external printed circuit board and the second connection region CA2 may be connected in the second-second region 2-2A.

The second electrode 220 may include a second-first electrode part 221 and a second-second electrode part 222. The second-first electrode part 221 may be disposed on at least one of the second-first region 2-1A and the second-second region 2-2A. Specifically, the second-first electrode part 221 may be disposed on the second-first region 2-1A and the second-second region 2-2A.

The second-second electrode part 222 may be disposed on at least one of the second-first region 2-1A and the second-second region 2-2A. Specifically, the second-second electrode part 222 may be disposed on the second-second region 2-2A. The second-second electrode part 222 may be disposed on an entire region or a partial region of the second-second region 2-2A.

The second-second electrode part 222 may be disposed on an edge of the second substrate 120. In detail, the second-second electrode part 222 may be disposed to extend along an edge of the second substrate 120.

Accordingly, the second-first electrode part 221 may be disposed in contact with the second substrate 120. Also, the second-second electrode part 222 may not be in contact with the second substrate 120. That is, the second-first electrode part 221 may be disposed on the second substrate 120. Also, the second-second electrode part 222 may be disposed on the second-first electrode part 221.

The second-second electrode part 221 and the second-second electrode part 222 may be disposed in different areas.

Specifically, an area of the second-first electrode part 221 may be greater than an area of the second-second electrode part 222. That is, the area of the second-first electrode part 221 disposed on the second-first region 2-1A and the second-second region 2-2A may be greater than the area of the second-second electrode part 222 disposed on the second-second region 2-2A.

In addition, the second-first electrode part 221 and the second-second electrode part 222 may have different thicknesses.

Specifically, the thickness T2-1 of the second-first electrode part 221 may be less than the thickness T2-2 of the second-second electrode part 222.

For example, the thickness T2-1 of the second-first electrode part 221 may be in a range of 0.1 μm to 0.5 μm. When the thickness T2-1 of the second-first electrode part 221 is less than 0.1 μm, it may be difficult to implement in a process. Also, a sheet resistance of the second-first electrode part 221 may increase. Also, when the thickness T2-1 of the second-first electrode part 221 exceeds 0.5 μm, the thickness of the optical path control member may increase.

In addition, the thickness T2-2 of the second-second electrode part 222 may be 0.1 μm to 5 μm. When the thickness T2-2 of the second-second electrode part 222 is less than 0.1 μm, it may be difficult to implement in a process. In addition, when the thickness T2-2 of the second-second electrode part 222 exceeds 5 μm, the thickness of the optical path control member may increase.

The thickness T2-1 of the second-first electrode part 221 may be less than the thickness T2-2 of the second-second electrode part 222 within the range.

In addition, the second-first electrode part 221 and the second-second electrode part 222 may include different materials.

The second-first electrode part 221 may include a transparent material. That is, the second-first electrode part 221 may include a transparent electrode. For example, the second-first electrode part 221 may include a metal oxide such as indium tin oxide, indium zinc oxide, copper oxide, tin oxide, zinc oxide, titanium oxide, etc.

Accordingly, even if the second-first electrode part 221 is disposed on the second-first region 2-1A of the second substrate 120, the luminance of the optical path control member may be maintained.

The second-second electrode part 222 may include an opaque or translucent material. The second-second electrode part 222 may include a metallic material. For example, the second-second electrode part 222 may include at least one of chromium (Cr), nickel (Ni), copper (Cu), aluminum (Al), silver (Ag), molybdenum (Mo). Gold (Au), titanium (Ti), and alloys thereof.

The second-second electrode part 212 is disposed on the second-second region 2-2A of the second substrate 120. Accordingly, even if the second-second electrode part 222 includes an opaque metallic material, it does not affect the transmittance of light passing through the optical path control member.

In addition, the second-first electrode part 221 and the second-second electrode part 222 may have different resistance values.

The resistance of the second-first electrode part 221 may be greater than that of the second-second electrode part 222. Specifically, the sheet resistance of the second-first electrode part 221 may be greater than that of the second-second electrode part 222.

For example, the sheet resistance of the second-first electrode part 221 may be 50Ω/□ to 2000Ω/□. Also, the sheet resistance of the second-second electrode part 222 may be 0.1Ω/□ to 50 Ω/□.

Accordingly, only an electrode having a high resistance may be disposed in the second-first region 2-1A, which is the active region of the second substrate 120. In addition, an electrode having a high resistance and a metal having a low resistance may be disposed together in the second-second region 2-2A, which is the inactive region of the second substrate 120.

Accordingly, the non-uniformity of the resistance may be reduced in the entire region of the second substrate 120. That is, when only the second-first electrode part 221 having a high resistance is disposed on the second substrate 120, the resistance may be increased while extending from the central portion of the second substrate 120 to the peripheral region. Accordingly, the second-second electrode part 222 having a low resistance may be additionally disposed on the second-second region 2-2A. Accordingly, the resistance non-uniformity may be reduced in the second substrate 120.

Accordingly, it is possible to minimize that the light conversion characteristics of the optical path control member vary for each region due to the electric field non-uniformity according to the difference in resistance. Accordingly, driving characteristics of the optical path control member may be improved.

In addition, the second-first electrode part 221 and the second-second electrode part 222 may have different transparency.

The transparency of the second-first electrode part 221 may be greater than that of the second-second electrode part 222. Specifically, the second-first electrode part 221 may be more transparent than the second-second electrode part 222.

Accordingly, even if the second-first electrode part 221 is disposed on the second-first region 2-1A of the second substrate 120, light passing through the optical path control member may transmit through the second-first electrode part 221.

In addition, the second-second electrode part 222 may include an opaque metallic material. However, the second-second electrode part 222 is disposed on the second-second region 2-2A through which light is not transmitted. Accordingly, it does not affect the transmittance of light passing through the optical path control member.

In addition, the second-first electrode part 221 and the second-second electrode part 222 may have different conductivity.

The conductivity of the second-second electrode part 222 may be greater than that of the second-first electrode part 221.

Since the conductivity of the second-second electrode part 222 is greater than that of the second-first electrode part 221, electrical connection characteristics between the optical path control member and the external printed circuit board may be improved.

That is, the second-second electrode part 222 is disposed at the second connection region CA2 in the second-second region 2-2A. Accordingly, the second connection region CA2 may include a material having high conductivity. Accordingly, when the optical path control member is connected to the external printed circuit board through the second connection region CA2, electrical connection characteristics may be improved.

A first electrode and a second electrode of the optical path control member according to the embodiment may include electrode parts having different areas, materials, thicknesses, resistances, transparency, and conductivity. Accordingly, a luminance of the optical path control member can be maintained. Additionally, the driving characteristics of the optical path control member can be improved.

That is, the optical path control member according to the embodiment may change a viewing angle by allowing light passing through the optical path control member to be transmitted by a first electrode part of a first electrode and the second electrode.

In addition, in the optical path control member according to the embodiment, resistance unevenness of the optical path control member may be reduced by a second electrode part of the first electrode and the second electrode.

Accordingly, electric field non-uniformity in a region of the optical path control member may be reduced. Accordingly, the optical path control member according to the embodiment may have improved light conversion characteristics. Accordingly, the optical path control member according to the embodiment may have improved driving characteristics.

Hereinafter, an optical path control member according to another embodiment will be described with reference to FIGS. 8 and 9. FIG. 8 is another cross-sectional view taken along a B-B′ region of FIG. 4, and FIG. 9 is another cross-sectional view taken along a C-C′ region of FIG. 6.

Referring to FIGS. 8 and 9, the first-first electrode part 211 and the first-second electrode part 212 may be disposed in contact with the first substrate 110. That is, the first-second electrode part 212 is not disposed on the first-first electrode 211, and the first-second electrode part 212 may be disposed in contact with the first substrate 110 on the first substrate 110.

In addition, the second-first electrode part 221 and the second-second electrode part 222 may be disposed in contact with the second substrate 120. That is, the second-second electrode part 212 is not disposed on the second-first electrode 221. The second-second electrode part 212 may be disposed in contact with the second substrate 120 on the second substrate 120.

Accordingly, a step difference between the first-first electrode part 211 and the first-second electrode part 212 may be reduced. In addition, a step difference between the second-first electrode part 221 and the second-second electrode part 222 may be reduced.

Accordingly, adhesion defects due to the size of the step difference may be reduced. Furthermore, the size of the step difference is reduced, and accordingly, the thicknesses of the first-second electrode part 212 and the second-second electrode part 222 may be increased. Accordingly, the resistance of the first-second electrode part 212 and the second-second electrode part 222 may be reduced. Accordingly, the size of the resistance non-uniformity of the optical path control member may be reduced.

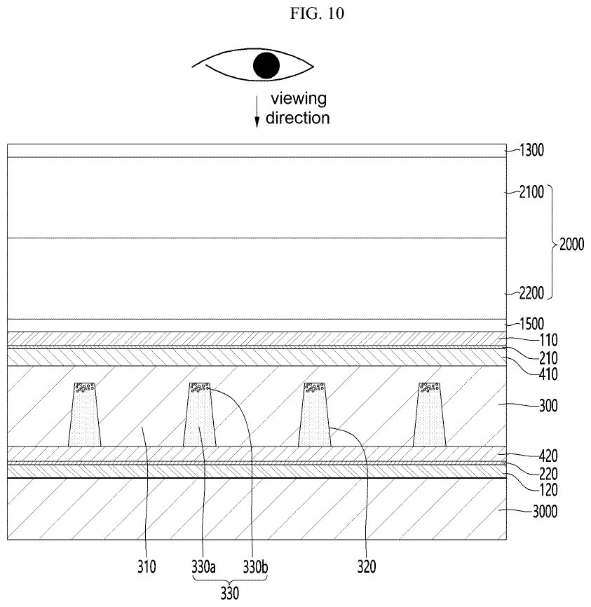

Hereinafter, a display device and a display device to which an optical path control member according to an embodiment is applied will be described with reference to FIGS. 10 to 14.

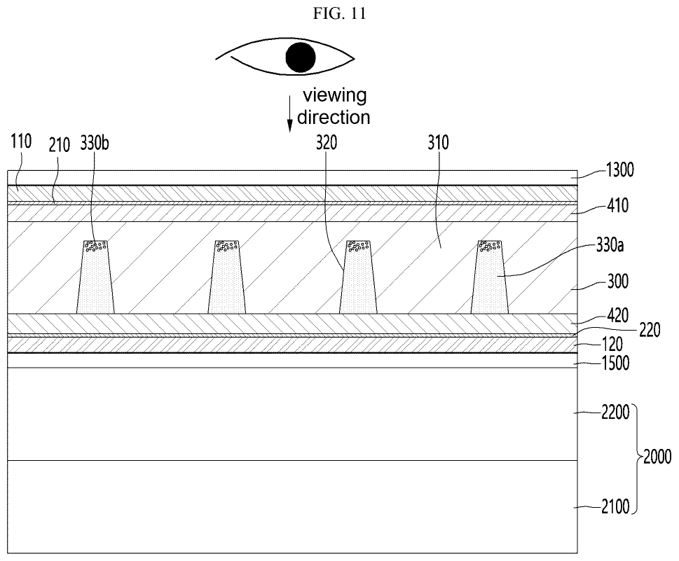

Referring to FIGS. 10 and 11, the optical path control member 1000 according to the embodiment may be disposed on or below the display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

The display panel 2000 may include a first base substrate 2100 and a second base substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first base substrate 2100 including a thin film transistor (TFT) and a pixel electrode and the second base substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first base substrate 2100 and the second base substrate 2200 is bonded to the first base substrate 2100 with the liquid crystal layer interposed therebetween. That is, a thin film transistor may be formed on the first base substrate 2100, a protective film may be formed on the thin film transistor, and a color filter layer may be formed on the protective film. In addition, a pixel electrode in contact with the thin film transistor may be formed on the first base substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 10, the optical path control member may be disposed under the liquid crystal panel and on the backlight unit 3000, and the optical path control member may be disposed between the backlight unit 3000 and the display panel 2000.

Alternatively, as shown in FIG. 11, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first base substrate 2100, and an organic light emitting element in contact with the thin film transistor may be formed. The organic light emitting element may include an anode, a cathode, and an organic light emitting layer formed between the anode and the cathode. In addition, the second base substrate 2200 configured to function as an encapsulation substrate for encapsulation may be further included on the organic light emitting element.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. Specifically, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the light conversion unit of the optical path control member according to the embodiment is in a direction parallel or perpendicular to an outer surface of the second substrate, but the light conversion unit is formed to be inclined at a predetermined angle from the outer surface of the second substrate. Through this, a moire phenomenon occurring between the display panel and the optical path control member may be reduced.

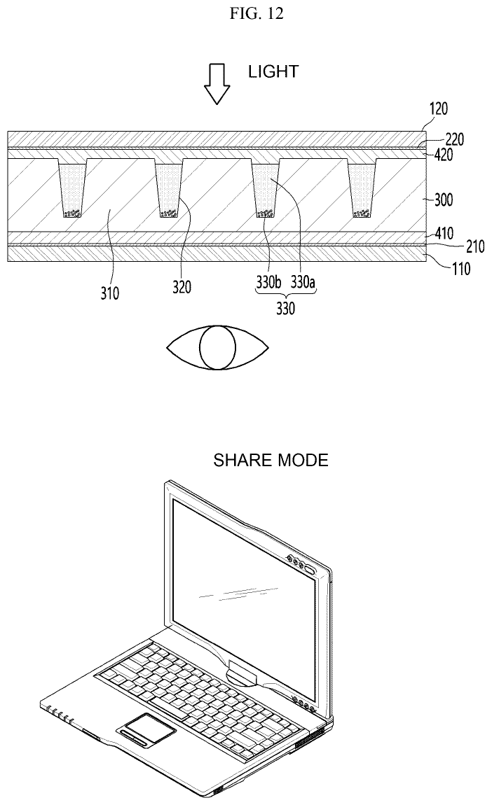

Referring to FIGS. 12 to 14, the optical path control member according to the embodiment may be applied to a display device that displays a display.

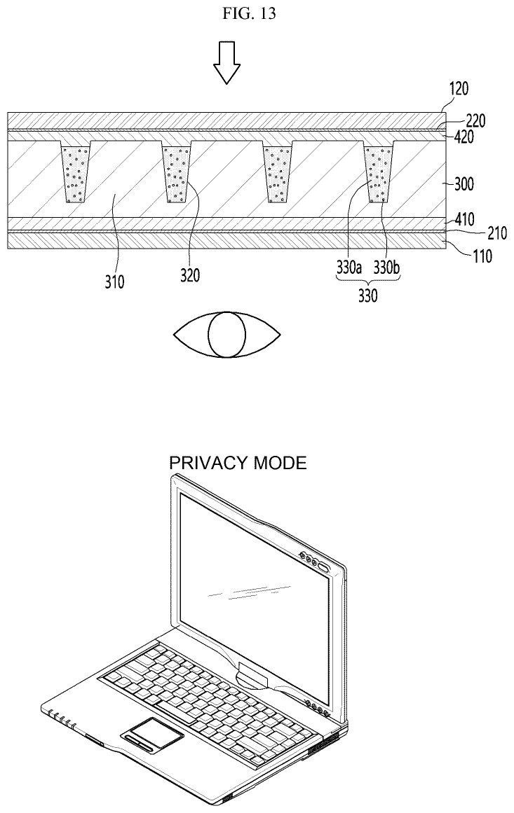

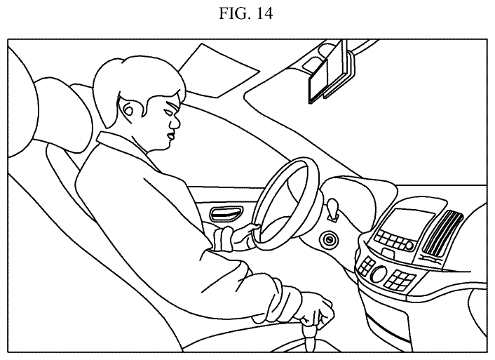

For example, when power is applied to the optical path control member as shown in FIG. 12, the accommodating part functions as the light transmitting part, so that the display device may be driven in the public mode, and when power is not applied to the optical path control member as shown in FIG. 13, the accommodating part functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 14, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. An optical path control member comprising:
a first substrate;
a first electrode disposed on the first substrate;
a second electrode disposed on the first electrode;
a second substrate disposed on the second electrode; and
a light conversion unit including a plurality of accommodating parts disposed between the first electrode and the second electrode and in which a light conversion material is disposed,
wherein the first substrate includes a first-first region overlapping the accommodating part along a thickness direction of the first substrate and a first-second region surrounding the first-first region and disposed at an edge of the first substrate,
wherein the second substrate includes a second-first region overlapping the accommodating part along the thickness direction and a second-second region surrounding the second-first region and disposed at an edge of the second substrate,
wherein the first electrode includes a first-first electrode part disposed on the first-first region and the first-second region and a first-second electrode disposed on the first-second region,
wherein the second electrode includes a second-first electrode part disposed on the second-first region and the second-second region and a second-second electrode part disposed on the second-second region,
wherein an area of the first-first electrode part is greater than an area of the first-second electrode part,
wherein an area of the second-first electrode part is greater than an area of the second-second electrode part, and
wherein the first-second electrode part is disposed on the first-second region while surrounding the first-first region.

2. The optical path control member of claim 1, wherein the first-second electrode part is disposed on the first-first electrode part, and
wherein the second-second electrode part is disposed on the second-first electrode part.

3. The optical path control member of claim 1, wherein a thickness of the first-first electrode part is smaller than that of the first-second electrode part, and
wherein a thickness of the second-first electrode part is smaller than that of the second-second electrode part.

4. The optical path control member of claim 3, wherein at least one of the first-first electrode part and the second-first electrode part has a thickness of 0.1 μm to 0.5 μm, and
wherein at least one of the first-second electrode part and the second-second electrode part has a thickness of 0.1 μm to 5 μm.

5. The optical path control member of claim 1, wherein a resistance of the first-first electrode part is greater than that of the first-second electrode part, and
wherein a resistance of the second-first electrode part is greater than that of the second-second electrode part.

6. The optical path control member of claim 1, wherein a transparency of the first-first electrode part is greater than that of the first-second electrode part, and
wherein a transparency of the second-first electrode part is greater than that of the second-second electrode part.

7. The optical path control member of claim 1, wherein a conductivity of the first-second electrode part is greater than that of the first-first electrode part, and
wherein a conductivity of the second-second electrode part is greater than that of the second-first electrode part.

8. The optical path control member of claim 1, wherein at least one of the first-first electrode part and the second-first electrode part includes indium tin oxide, indium zinc oxide, copper oxide, tin oxide, zinc oxide, or titanium oxide, and
wherein at least one of the first-second electrode part and the second-second electrode part includes at least one metal of chromium (Cr), nickel (Ni), copper (Cu), aluminum (Al), silver (Ag), molybdenum (Mo). Gold (Au), titanium (Ti), and any alloys thereof.

9. The optical path control member of claim 1, wherein the first-first electrode part and the first-second electrode part are disposed in contact with the first substrate, and
wherein the second-first electrode part and the second-second electrode part are disposed in contact with the second substrate.

10. The optical path control member of claim 1, wherein a first connection region is disposed in the first-second region, and
wherein a second connection region is disposed in the second-second region.

11. The optical path control member of claim 1, wherein the second-second electrode part is disposed on the second-second region while surrounding the second-first region.

12. The optical path control member of claim 10, wherein the first-second electrode part includes a first portion disposed in the first connection region and a second portion disposed in a region other than the first connection region, and
wherein a width of the first portion is larger than a width of the second portion.

13. The optical path control member of claim 10, wherein the second-second electrode part includes a third portion disposed in the second connection region and a fourth portion disposed in a region other than the second connection region, and
wherein a width of the third portion is larger than a width of the fourth portion.

14. The optical path control member of claim 1, wherein an outer surface of the first-first electrode part and an outer surface of the first-second electrode part have a step difference.

15. The optical path control member of claim 14, wherein the outer surface of the first-first electrode part is disposed further outside than the outer surface of the first-second electrode part.

16. The optical path control member of claim 1, wherein an outer surface of the second-first electrode part and an outer surface of the second-second electrode part have a step difference.

17. The optical path control member of claim 16, wherein the outer surface of the second-first electrode part is disposed further outside than the outer surface of the second-second electrode part.

18. The optical path control member of claim 1, wherein the first-second region includes a first sub-region in which the first-second electrode part is disposed, and a second sub-region surrounding the first sub-region and in which the first-first electrode part is disposed.

19. The optical path control member of claim 1, wherein the second-second region includes a third sub-region in which the second-second electrode part is disposed, and a fourth sub-region surrounding the third sub-region and in which the second-first electrode part is disposed

20. A display device comprising:
a panel including at least one of a display panel or a touch panel; and
the optical path control member of claim 1 disposed on or under the panel.
